(19) United States
(12) Patent Application Publication
(10) Pub. No.: US 2015/0060826 A1
(43) Pub. Date: Mar. 5, 2015

(54) LIGHT EMITTING DISPLAY DEVICE AND MANUFACTURING METHOD THEREOF

(71) Applicant: Japan Display Inc., Tokyo (JP)

(72) Inventors: Yuko MATSUMOTO, Tokyo (JP); Toshihiro SATO, Tokyo (JP)

(73) Assignee: Japan Display Inc.

(21) Appl. No.: 14/474,428

(22) Filed: Sep. 2, 2014

(30) Foreign Application Priority Data
Sep. 2, 2013 (JP) 2013-181095

(51) Int. Cl. H01L 27/32; H01L 51/56

(52) U.S. Cl. CPC H01L 27/3246; H01L 51/56
USPC 257/40; 438/34

(57) ABSTRACT

A light emitting display device includes a first substrate having a display area in which pixels are arranged in a matrix. The first substrate includes: a light emitting organic layer that includes a light emitting layer that emits a light in the pixels, and is made of an organic material; first electrodes that are one of two electrodes arranged to sandwich the light emitting organic layer therebetween, and arranged in the respective pixels, independently; a second electrode that is the other of the two electrodes, and arranged to cover the overall display area; and insulating banks that cover ends of the first electrodes, and are arranged to bring the electrodes between the respective pixels out of contact with each other. A surface of the insulating banks has roughness with a cycle equal to or larger than a visible light wavelength, and smaller than a thickness of the insulating banks.

### CROSS-REFERENCE TO RELATED APPLICATION

The present application claims priority from Japanese patent application JP2013-181095 filed on Sep. 2, 2013, the content of which is hereby incorporated by reference into this application.

### BACKGROUND OF THE INVENTION

1. Field of the Invention

The present invention relates to a light emitting display device, and a method of manufacturing the light emitting display device, and more particularly to a light emitting display device, and a method of manufacturing the display device, which allow light emitting elements that are self-luminous bodies arranged in the respective pixels to emit a light for display.

2. Description of the Related Art

In recent years, image display devices (hereinafter referred to as “organic EL (electro-luminescent) display device”) using self-luminous bodies called “organic light emitting diodes (OLED)” have been put into practical use. As compared with a related art liquid crystal display device, the organic EL display device not only is excellent in visibility and response speed because of the use of the self-luminance bodies, but also can be further thinned because of no need of an auxiliary lighting device such as a backlight.

In color display on the organic EL display device of this type, there are mainly two kinds of cases in which light emitting elements emit respective lights of three colors of R (red), G (green), and B (blue) in each of the pixels, and in which light emitting elements emit white lights, and color filters of the respective pixels transmit the respective wavelength regions of three colors of RGB.

An insulating bank made of an insulating material which is formed to surround a light emitting area is formed around each of the pixels in the organic EL display device. The insulating bank is formed to surround a light emitting area of an anode electrode, to thereby prevent a cathode electrode and the anode electrode from coming in contact with each other. Also, the insulating bank surrounds the light emitting area, to thereby increase a distance between the adjacent pixels due to a step of the insulating bank, and reduce a current leakage in a horizontal direction. Because the insulating bank is normally formed of a film made of an organic or inorganic insulating material, and transmits light inmost cases, a light is leaked into the adjacent pixels through the insulating bank, resulting in a risk that colors are mixed together.

JP 2004-288447 A discloses that a layer higher in refractive index than an insulating bank is formed on a surface of the insulating bank to reflect the light. JP 2007-157404 A discloses a reflecting surface having a function of reflecting the light, which is present on an inner surface of an insulating bank disposed to partition organic light emitting elements. JP 2004-111354 A discloses that irregularities larger than a wavelength of light are formed on a glass substrate on which light emitting elements are formed.

### SUMMARY OF THE INVENTION

However, counter measures against light leakage to the adjacent pixels disclosed in the above Patent Literatures are not sufficient. The present invention has been made in view of the above-mentioned circumstances, and an object of the present invention is to provide a light emitting display device that suppresses the light from being leaked to the adjacent pixels, and improves a light extraction efficiency.

According to the present invention, there is provided a light emitting display device including a first substrate having a display area in which pixels are arranged in a matrix, the first substrate including: a light emitting organic layer that includes at least a light emitting layer that emits a light in the pixels, and is made of an organic material; first electrodes that are one of two electrodes arranged to sandwich the light emitting organic layer therebetween, and arranged in the respective pixels, independently; a second electrode that is the other of the two electrodes, and arranged to cover the overall display area; and insulating banks that cover ends of the first electrodes, and are arranged to set no continuity of the electrodes between the respective pixels, in which a surface of the insulating banks has roughness with a cycle equal to or larger than a visible light wavelength, and smaller than a thickness of the insulating banks.

Also, in the light emitting display device according to the present invention, each of the insulating banks may include a first photosensitive organic material that dissolves in an etching solution by exposure to a light, and a second photosensitive organic material that decomposes into low molecules by exposure to the light.

Also, in the light emitting display device according to the present invention, the roughness is formed in a cycle of 300 nm to 2 μm.

According to the present invention, there is provided a method of manufacturing a light emitting display device, including the steps of: forming first electrodes that are one of two electrodes to be arranged, and arranged in respective pixels, independently; forming insulating banks that cover ends of the first electrodes, and are arranged to establish no continuity of the electrodes between the respective pixels; forming a light emitting organic layer that covers at least the first electrodes, includes at least a light emitting layer, and is made of an organic material; and forming a second electrode that is the other of the two electrodes, and arranged to cover the overall display area, in which the step of forming the insulating banks includes the steps of: coating and burning a mixed material of a first photosensitive organic material that dissolves in an etching solution by exposure to a light, and a second photosensitive organic material that decomposes into low molecules by exposure to the light to form a thin film; exposing and etching the thin film to perform patterning; and further exposing and burning the patterned thin film to form surface roughness in a cycle equal to or larger than a visible light wavelength, and smaller than a thickness of the insulating banks.

### BRIEF DESCRIPTION OF THE DRAWINGS

FIG. 1 is a diagram schematically illustrating an organic EL display device according to an embodiment of the present invention;

FIG. 2 is a diagram illustrating a configuration of an organic EL panel in FIG. 1;

FIG. 3 is a diagram schematically illustrating a cross-section of a TFT substrate taken along a line III-III in FIG. 2;

FIG. 4 is a flowchart illustrating a process of manufacturing the TFT substrate which is one process of manufacturing the organic EL display device;

FIG. 5 is a flowchart illustrating details of a process of forming an insulating bank of the FIG. 4;

FIG. 6 is a flowchart illustrating a first modified example of the process of forming the insulating bank; and

FIG. 7 is a flowchart illustrating a second modified example of the process of forming the insulating bank.

### DETAILED DESCRIPTION OF THE INVENTION

Hereinafter, embodiments of the present invention will be described with reference to the drawings. In the drawings, the same or equivalent elements are denoted by identical symbols, and a repetitive description will be omitted.

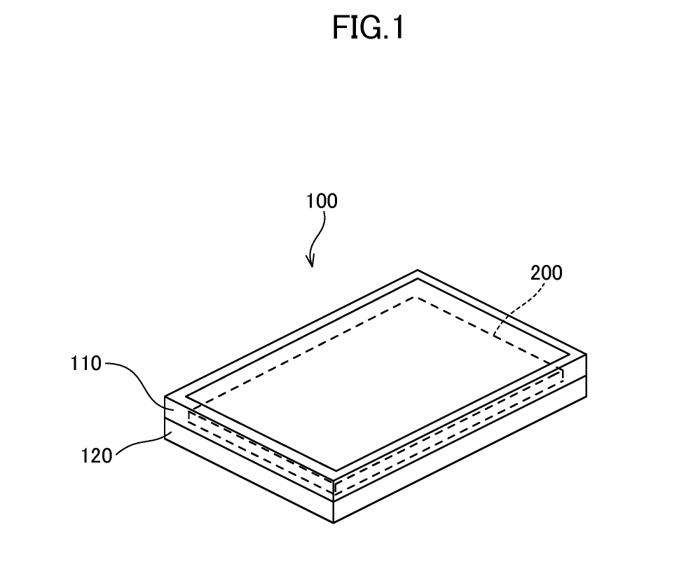

FIG. 1 is a diagram schematically illustrating an organic EL display device 100 according to an embodiment of the present invention. As illustrated in FIG. 1, the organic EL display device 100 includes an organic EL panel 200 fixed to be sandwiched between an upper frame 110 and a lower frame 120.

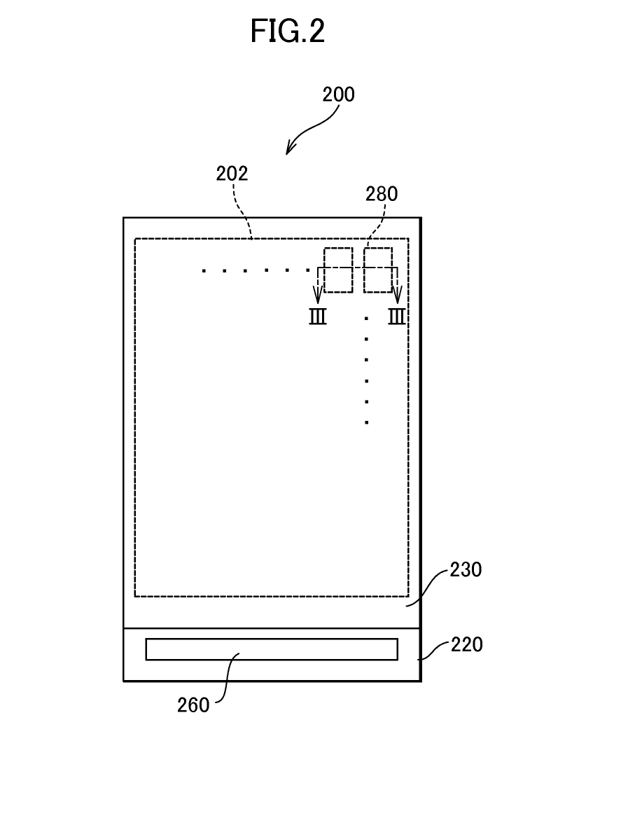

FIG. 2 is a diagram illustrating a configuration of the organic EL panel 200 in FIG. 1. The organic EL panel 200 includes two substrates of a first substrate (hereafter, it is described TFT (thin film transistor) substrate) 220, and a second substrate (hereafter, it is described sealing substrate) 230, and a space between those substrates is filled with a transparent resin (not shown). The TFT substrate 220 has pixels 280 arranged in a matrix in a display area 202. The pixel has a pixel circuit. Also, the TFT substrate 220 includes a drive IC (integrated circuit) 260 that is a driver circuit that applies a potential for establishing a continuity between a source and a drain to scanning signal lines (not shown) of pixel transistors arranged in the respective pixels, and also applies a voltage corresponding to a gradation value of the pixel to data signal lines of the respective pixel transistors.

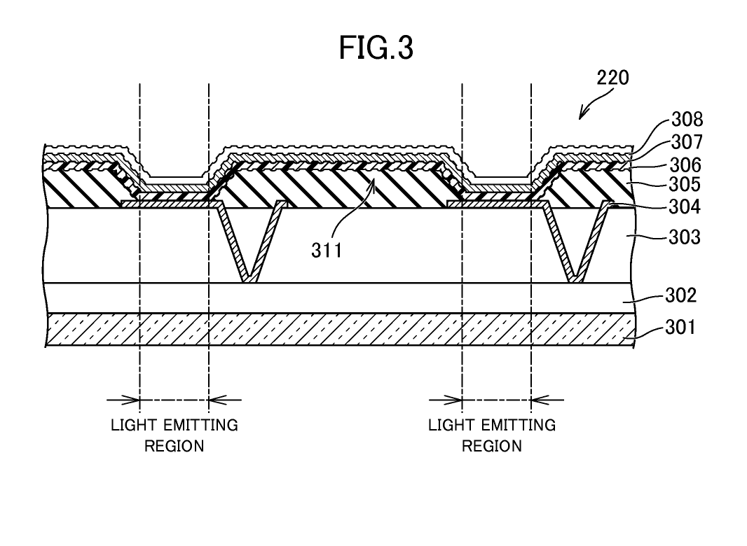

FIG. 3 is a diagram schematically illustrating a cross-section of the TFT substrate 200 taken along a line III-III in FIG. 2. As illustrated in FIG. 3, the TFT substrate 220 includes a glass substrate 301 that is an insulating substrate; a TFT circuit layer 302 which is a circuit using a TFT formed on the glass substrate 301, a planarizing film 303 made of an insulating material which is formed on the TFT circuit layer 302; anode electrodes 304 connected to the circuit of the TFT circuit layer 302 through through-holes opened in the planarizing film. 303, insulating banks 305 that cover ends of the respective anode electrodes 304, and insulate the electrodes from each other between the respective pixels, an organic layer 306 including common layers such as a light emitting layer, an electron injection layer, and a hole transport layer which is formed over the anode electrodes 304 and the insulating banks 305 so as to cover the overall display area 202, a cathode electrode 307 that is formed on the organic layer 306 so as to cover the overall display area 202, and a sealing film 308 that blocks air and water for preventing the deterioration of the organic layer 306.

This embodiment assumes the organic EL display device 100 of a system in which the light having the same wavelength region (for example, W (white)) is emitted in the overall display area, and the light of wavelength regions corresponding to RGB is extracted by color filters disposed on the sealing substrate 230. However, the present invention is not limited to the above configuration, but may be applied to a display device of a system in which the light having the respective wavelength regions of RGB is emitted in the respective pixels, and the light is extracted without the use of the color filters. In this case, the organic layer including the light emitting layer is painted into a dotted shape or a stripe shape for each of the pixels, separately, and formed by vapor deposition.

In this example, roughness (surface roughness) 311 of a cycle that is equal to or larger than a visible wavelength (about 300 nm to 800 nm), and smaller than a thickness (about 2 μm) of the insulating banks 305 are formed on the surfaces of the insulating banks 305. Specifically, the roughness 311 having a cycle of about 300 nm to 2 μm are formed. With the formation of the above roughness, the light emitted from the light emitting layer is diffused on the surfaces of the insulating banks 305, and the transmission of the light through the insulating banks 305 can be reduced. With this configuration, color mixture such that light is leaked from the adjacent pixels is reduced, and the effective amount of light on a front surface increases, as a result of which the light emission efficiency can be enhanced. Also, with the provision of the roughness 311, a distance between the respective adjacent pixels becomes large, and the resistance increases whereby a current leak can be also reduced.

The insulating banks 305 can be made of a photosensitive polyimide material as well as acrylic-type or azo-type photosensitive polymer material, and may be made of a material containing polyimide decomposing into low molecules by irradiation of ultraviolet rays used for a photo-alignment film of known liquid crystal display devices.

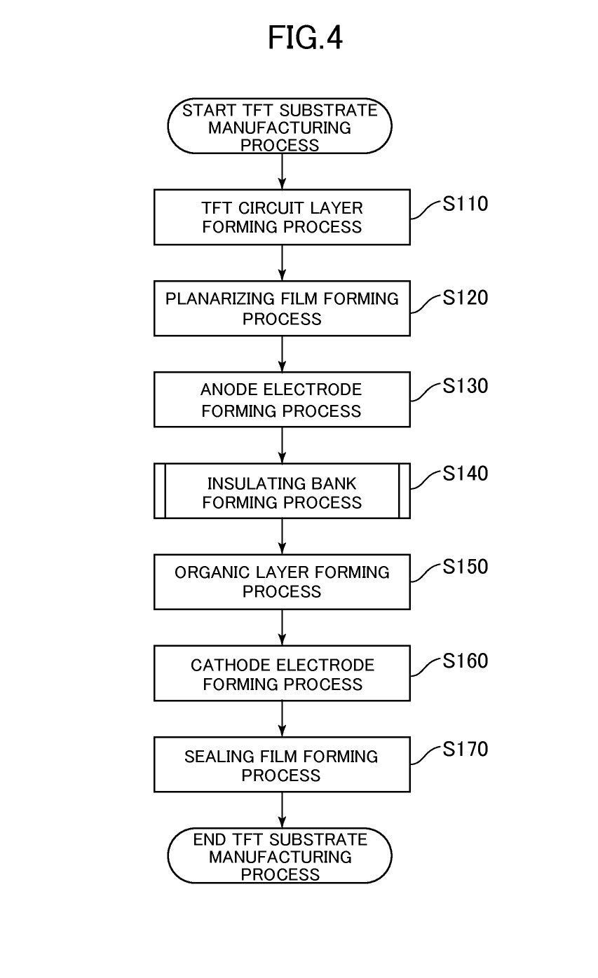

FIG. 4 is a flowchart illustrating an example of a process of manufacturing the TFT substrate 220 which is one process of manufacturing the organic EL display device 100. As illustrated in FIG. 4, in the TFT substrate manufacturing process, first, in a TFT circuit layer forming process S110, the TFT circuit layer 302 is formed on the glass substrate 301 through a normal photolithography process. Then, in a planarizing film forming process S120, the planarizing film 303 is formed. In the planarizing film forming process S120, a through-hole for conducting an electric connection between the anode electrode 304 and the TFT circuit which will be described later is also formed. In this example, it is desirable that the planarizing film is made of a polyimide material because an acrylic material that is metamorphosed when being heated is improper if the planarizing film is formed for a top emission, and burned at high temperature later.

Then, in an anode electrode forming process S130, the anode electrodes 304 are formed. In this situation, the anode electrodes 304 are also formed within the through-hole formed in the planarizing film 303. In the top emission structure, in order to form the anode electrodes 304 as the reflective electrodes, Ag or the like is used. Continuously, in an insulating bank forming process S140, the insulating bank 305 is formed to cover the ends of the anode electrodes 304, and a portion between the light emitting areas of the two pixels 280. The details of the insulating bank forming process will be described later.

Subsequently, in an organic layer forming process S150, the organic layer 306 including the common layers such as the light emitting layer, the electron injection layer, and the hole transport layer is formed. The organic layer 306 may be formed through any one of a vapor deposition technique and a printing technique, for example, colors of RGB may be painted for each of the pixels, separately, or the light emitting layer of white may be formed over the overall display area. Continuously, in a cathode electrode forming process S160, the common cathode electrode 307 is formed on the organic layer 306. In the top emission, a transparent or semitransparent electrode material combining, for example, ITO, IZO (registered trademark), Ag and the like together is used. Finally, in a sealing film forming process S170, the sealing film 308 that blocks air and water for preventing the deterioration of the organic layer 306 is formed on the cathode electrode 307. Sealing using a glass cap, or solid sealing made of SiN may be applied.

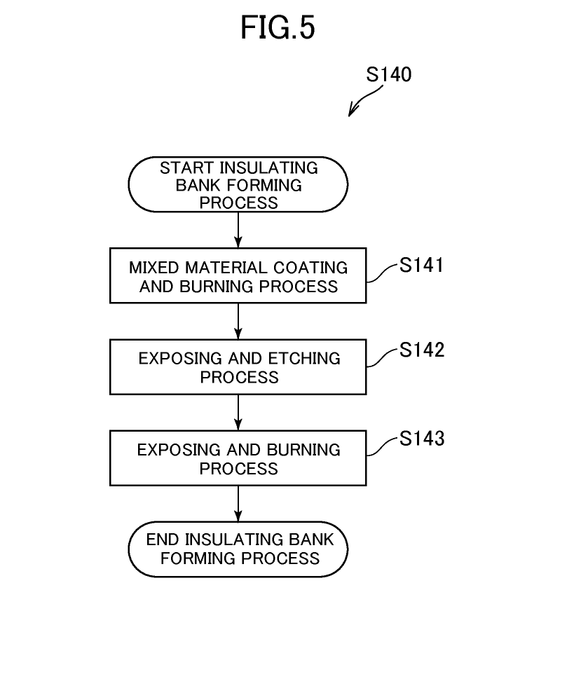

FIG. 5 is a flowchart illustrating details of the insulating bank forming process S140 of FIG. 4. In this embodiment, the insulating banks 305 are made of a mixture of the first photosensitive organic material that dissolves in the etching solution by exposure to a light, and the second photosensitive organic material that decomposes into low molecules by exposure to the light.

As illustrated in this flowchart, in the insulating bank forming process S140, first in a mixed material coating firing process S141, a mixed material in which the first photosensitive organic material and the second photosensitive organic material are mixed together, and dissolves in a solvent in a state of polyamide acid is prepared, and the mixed material is coated and burned on a substrate by printing to form a thin film of polyimide. Then, in an exposing and etching process S142, a portion to be etched is exposed to light of a desired wavelength, and immersed in an etching solution to perform patterning a bank shape. In this situation, a portion of the first photosensitive organic material which is exposed to the light in the mixed two photosensitive materials dissolves in the etching solution.

Continuously, in an exposing and burning process S143, the formed bank shape is irradiated with light, for example, through an optical mask, and a polyamide material which is the second photosensitive organic material of the portion that absorbs the light decomposes into low molecules to form the low molecular portions in a desired cycle. It is desirable that, on the surface, the desired cycle is equal to or larger than a visible wavelength (about 300 nm to 800 nm), and smaller than a thickness (about 2 μm) of the insulating banks. The wavelength region of the irradiated light can be arbitrarily designated, but a wavelength of an ultraviolet region of about 150 to 420 nm is desired, and it is desirable that the amount of light irradiation is adjusted in a region of 50 nm to 500 nm in a depth direction from the surface by adjusting illuminance or an irradiation time. Thereafter, the insulating banks are heated at 200° C. or higher, and polyimide that has decomposed into low molecules is evaporated. As a result, the evaporated portion is recessed to form an uneven structure.

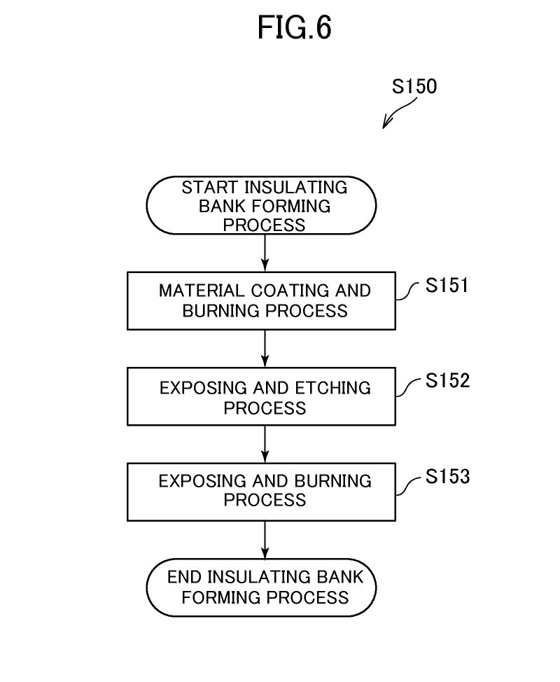

FIG. 6 is a flowchart illustrating a first modified example of an insulating bank forming process S150. In the insulating bank forming process S140, the mixed material into which the first photosensitive organic material and the second photosensitive organic material are mixed together is coated. However, the present invention is not particularly limited to the mixed material, but in an exposure etching process S151 and an exposing and burning process S152, a material in which the uneven structure is formed may be used.

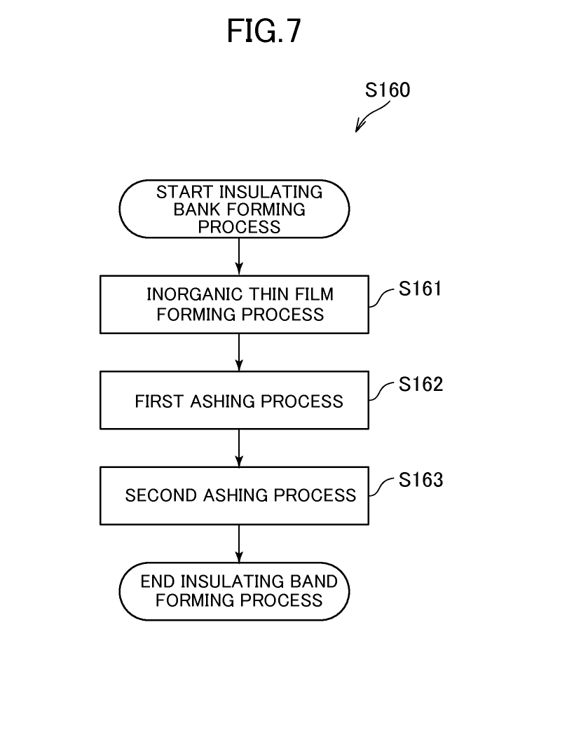

FIG. 7 is a flowchart illustrating a second modified example of an insulating bank forming process S160. In the insulating bank forming process S140, the organic material is used, but an inorganic material can be used. In this case, the exposing and etching process S141 and the exposing and burning process S142 in the insulating bank forming process S140 can be replaced with a first ashing process S162 and a second ashing process S163 using ashing.

As has been described above, in the above-mentioned embodiments, because the roughness are formed in the insulating banks 305, the light emitted from the light emitting layer is diffused on the surfaces of the insulating banks 305, and the transmission of the light through the insulating banks 305 can be reduced. Also, with the above configuration, color mixture such that light is leaked from the adjacent pixels is reduced, and the effective amount of light on a front surface increases, as a result of which the light emission efficiency can be enhanced. Also, with the provision of the roughness 311, a distance between the respective adjacent pixels becomes large, and the resistance increases whereby a current leak can be also reduced.

In the above embodiment, the light emitting display device of the top emission system is applied, but a bottom emission system may be used. Also, the light emitting layer uses the light emitting elements classified into so-called organic EL, but another self-luminescent element that emits light by itself may be used. Also, the cross-section of FIG. 3 illustrates an example in which the organic layers of the same type are formed, but organic layers different for each of the pixels may be formed. In the above-mentioned embodiment, the organic material is used for the insulating banks, but an inorganic material may be used to form the same roughness.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A light emitting display device comprising a first substrate having a display area in which pixels are arranged in a matrix, the first substrate including:
a light emitting organic layer that includes at least a light emitting layer that emits a light in the pixels, and is made of an organic material;
first electrodes that are one of two electrodes arranged to sandwich the light emitting organic layer therebetween, and arranged in the respective pixels, independently;
a second electrode that is the other of the two electrodes, and arranged to cover the overall display area; and
insulating banks that cover ends of the first electrodes, and are arranged to set no continuity of the electrodes between the respective pixels,
wherein a surface of the insulating banks has roughness with a cycle equal to or larger than a visible light wavelength, and smaller than a thickness of the insulating banks.

2. The light emitting display device according to claim 1,
wherein the insulating banks each includes a first photosensitive organic material that dissolves in an etching solution by exposure to a light, and a second photosensitive organic material that decomposes into low molecules by exposure to the light.

3. The light emitting display device according to claim 1,
wherein the roughness is formed in a cycle of 300 nm to 2 μm.

4. A method of manufacturing a light emitting display device, comprising the steps of:
forming first electrodes that are one of two electrodes to be arranged, and arranged in respective pixels, independently;
forming insulating banks that cover ends of the first electrodes, and are arranged to establish no continuity of the electrodes between the respective pixels;
forming a light emitting organic layer that covers at least the first electrodes, includes at least a light emitting layer, and is made of an organic material; and
forming a second electrode that is the other of the two electrodes, and arranged to cover the overall display area,
wherein the step of forming the insulating banks includes the steps of:
coating and burning a mixed material of a first photosensitive organic material that dissolves in an etching solution by exposure to a light, and a second photosensitive organic material that decomposes into low molecules by exposure to the light to form a thin film;
exposing and etching the thin film to perform patterning; and
further exposing and burning the patterned thin film to form surface roughness in a cycle equal to or larger than a visible light wavelength, and smaller than a thickness of the insulating banks.
